(19) United States
(12) Patent Application Publication
(10) Pub. No.: US 2013/0017665 A1
(43) Pub. Date: Jan. 17, 2013

(54) METHODS OF FORMING ISOLATION STRUCTURE AND SEMICONDUCTOR STRUCTURE

(71) Applicants: Haizhou Yin, Poughkeepsie, NY (US); Huilong Zhu, Poughkeepsie, NY (US); Zhijiong Luo, Poughkeepsie, NY (US)

(72) Inventors: Haizhou Yin, Poughkeepsie, NY (US); Huilong Zhu, Poughkeepsie, NY (US); Zhijiong Luo, Poughkeepsie, NY (US)

(21) Appl. No.: 13/380,807

(22) PCT Filed: Aug. 5, 2011
(86) PCT No.: PCT/CN11/01291

§ 371 Date: Dec. 23, 2011

(30) Foreign Application Priority Data
Jul. 13, 2011 (CN) 2011101954390

(51) Int. Cl. H01L 21/762

(52) U.S. Cl. 438/424; 257/E21.546

(57) ABSTRACT

The present invention relates to a method of forming an isolation structure and a semiconductor structure. The method of forming the isolation structure comprises the steps of: providing a silicon substrate having a (110) crystal plane or a (112) crystal plane and determining the [111] direction of the silicon substrate; forming first trenches in the silicon substrate by wet etching the silicon substrate, the extension direction of the first trenches being substantially perpendicular to the [111] direction; filling the first trenches with a first insulating material to form a first isolator; forming second trenches in the silicon substrate by dry etching the silicon substrate, the extension direction of the second trenches being perpendicular to the extension direction of the first trenches; filling the second trenches with a second insulating material to form a second isolator.

### FIELD OF THE INVENTION

The present invention generally relates to a method of forming a semiconductor device, and in particular, to a method of forming an isolation structure in the semiconductor device.

### BACKGROUND OF THE INVENTION

Modern semiconductor devices, such as Metal Oxide Semiconductor (MOS) devices, are usually formed on a surface of a semiconductor substrate, such as a silicon substrate. Semiconductor devices are separated from each other by an isolation structure. A common isolation structure comprises one of junction isolation, Local Oxidation of Silicon (LOCOS) isolation and Shallow Trench Isolation (STI), and the like.

With the continuous development of semiconductor device technologies, the critical dimensions (CDs) of semiconductor devices are continuously scaling down, and in this case, the isolation technique between the devices becomes increasingly important, since the quality of the isolation technique directly determines leakage characteristic, breakdown characteristic and latch-up effect of the entire circuit. One of the requirements on the isolation technique is not increasing defects during the manufacture of semiconductor devices. As semiconductor device technologies proceed into the deep sub-micron era, the Shallow Trench Isolation technique has become a widely adopted isolation technique for semiconductor devices due to its unique advantages. The STI structure is usually formed by the steps of forming trenches on a substrate by dry etching first, and filling the trenches with an insulating material by means of Chemical Vapor Deposition, then removing the insulating material on the surfaces of the trenches and the substrate by means of Chemical Mechanical Polishing to planarize the surfaces of the trenches.

However, with further reduction of the dimensions of semiconductor devices, the device width is much smaller than the device length. For example, the device width is even as small as under 80 nm FIG. 8a is a cross-sectional view of a MOS device, and FIG. 8b is a top view of the device of FIG. 8a. As shown in FIG. 8b, viewing from the direction of the width of the device, the upper and lower STI structures along the lateral direction as shown in the figure carry the two end portions of the gate. But during formation of the STI, the selection ratio of the dry etching for forming the trench is not high, so it tends to generate defects in the trench sidewalls, and possibly to form an undercut in the etched trench. Any defect caused by the dry etching of the STI in the trench sidewalls might have adverse effects on the gate of the device.

Therefore, there is a need for an improved isolation technique to reduce the defects caused by the dry etching in the trench sidewalls.

### SUMMARY OF THE INVENTION

An object of the present invention is to provide a method of forming an isolation structure, which can reduce the defects caused by the dry etching of the STI in the trench sidewalls, thereby reducing the adverse effects on the gate of the device.

To achieve the above object, the present invention provides a method of forming an isolation structure, the isolation structure being used for isolating at least one isolation region, the method comprising:

providing a silicon substrate having a (110) crystal plane or a (112) crystal plane;

forming one or more first trenches in a first direction of the silicon substrate by wet etching;

filling the first trenches with a first insulating material to form one or more first isolators;

forming one or more second trenches in a second direction of the silicon substrate; and

filling the second trenches with a second insulating material to form one or more second isolators, the second isolators being joined to the first isolators to form the isolation structure;

wherein the angle between the crystal orientation of one sidewall of the first trench and the [111] direction of the silicon substrate is no more than 3°.

The present invention also provides a method of forming a semiconductor structure, the method comprising:

forming at least one isolation structure by a method of forming the isolation structure according to the present invention;

forming one or more gates on regions isolated by the isolation structure, two end portions of each of the gates being located on corresponding one of the first isolators.

Compared to the prior art, the present invention has the following advantages:

In the present invention, the isolation structure is formed on the silicon substrate having the (110) crystal plane or the (112) crystal plane, and one of the sidewalls of the first trench formed by wet etching the silicon substrate is on the (111) plane of the silicon substrate. It is well known that wet etching causes less damages to the device than dry etching, so forming the first trenches by using wet etching will cause less damages to the sidewalls of the trenches than the case of using dry etching, thereby reducing the defects occurring in the sidewalls of the trenches and reducing the adverse effects on the gate of the device.

Second, the wet etching using an etchant such as KOH or TMAH is highly selective to the (111) plane of the silicon substrate, and one of the sidewalls of the first trench is located on the (111) plane of the silicon substrate, so that the undercut that might occur under the sidewalls of the trenches is avoided to a great extent, which can reduce the leakage current of the device and improve the performance of the device.

### BRIEF DESCRIPTION OF THE DRAWINGS

These and other features and advantages of the present invention will be apparent from the following detailed description with reference to the accompanying drawings, in which:

FIG. 1 is a cross-sectional view of a structure corresponding to an intermediate step of the method of forming an isolation structure according to an embodiment of the present invention;

FIG. 2a is a cross-sectional view of the structure corresponding to an intermediate step of the method of forming the isolation structure according to the embodiment of the present invention;

FIG. 2b is a top view of the structure shown in FIG. 2a;

FIG. 3 is a cross-sectional view of the structure corresponding to an intermediate step of the method of forming the isolation structure according to the embodiment of the present invention;

FIG. 4a is a cross-sectional view of the structure corresponding to an intermediate step of the method of forming the isolation structure according to the embodiment of the present invention;

FIG. 4b is a top view of the structure shown in FIG. 4a;

FIG. 5a is a cross-sectional view of the structure corresponding to an intermediate step of the method of forming the isolation structure according to the embodiment of the present invention;

FIG. 5b is a top view of the structure shown in FIG. 5a;

FIG. 6 is a cross-sectional view of the structure corresponding to an intermediate step of the method of forming a semiconductor structure according to the embodiment of the present invention;

FIG. 7 is a flow chart of the method of forming the isolation structure according to the embodiment of the present invention;

FIG. 8 is a schematic drawing showing a device having an STI structure in the prior art, wherein FIG. 8a is a cross-sectional view of the device and FIG. 8b is a top view of the device shown in FIG. 8a.

### DETAILED DESCRIPTION OF THE PREFERRED EMBODIMENTS

Embodiments of the present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout. Furthermore, the various layers and regions illustrated in the figures are illustrated schematically and are not necessarily drawn to scale. Accordingly, the present invention is not limited to the relative size, spacing and alignment illustrated in the accompanying figures. As will also be appreciated by those of skill in the art, references herein to a layer formed “on” a substrate or other layer may refer to the layer formed directly on the substrate or other layer or on an intervening layer or layers formed on the substrate or other layer.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

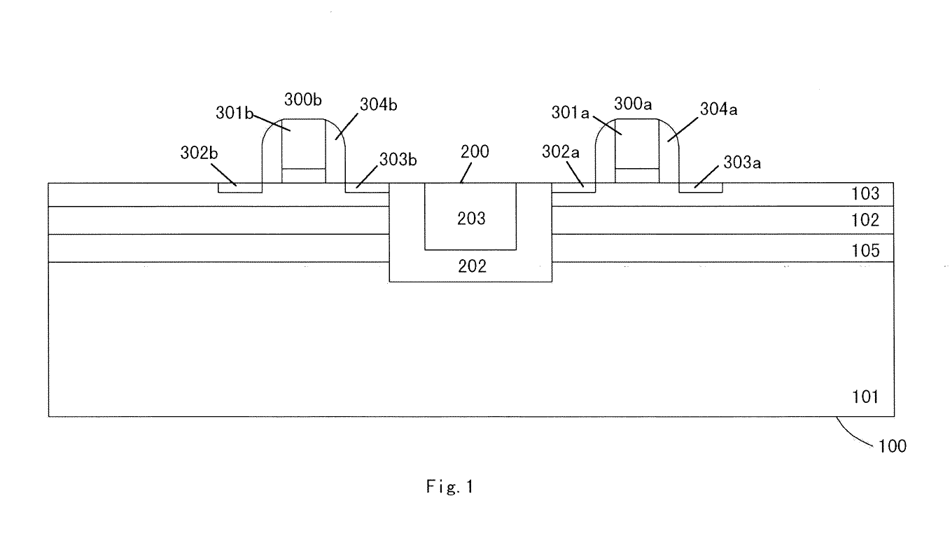

The method of forming the isolation structure according to the embodiment of the present invention will be described below with reference to FIGS. 1-5.

As shown in FIG. 1, a silicon wafer having a (110) crystal plane or a (112) crystal plane is provided as a semiconductor substrate 1000, and the [111] direction of the silicon wafer is determined. An oxide layer 1002 is grown on the substrate 1000 as the pad oxide layer, which can be, for example, a silicon oxide layer. Then a nitride layer 1004 is deposited on the oxide layer 1002 as the pad nitride layer, which can be, for example, a silicon nitride layer. Next, a photoresist layer 1005 is coated on the nitride layer 1004.

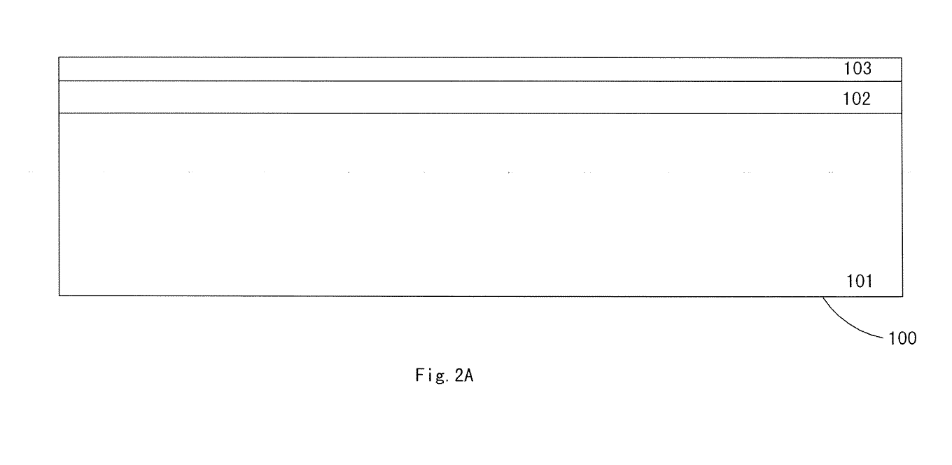

Next, the photoresist layer 1005 is patterned to form openings. The angle between the extension direction of the opening and the [111] direction is within the range of 87°-90° (inclusive); that is, the extension direction of the opening is substantially perpendicular to the [111] direction; preferably, they are perpendicular to each other (because such technologies as the semiconductor processing technology might result in deviation of the pattern structure, the extension direction of the opening might not be completely perpendicular to the [111] direction in practice, and said “perpendicular” means to substantially perpendicular within the range of error allowed by the current semiconductor technology). The patterned photoresist layer 1005 is used as a mask so as to perform a wet etching operation to remove parts of the nitride layer 1004, the oxide layer 1002 and the substrate 1000 under the openings, thereby forming trenches 1006 in the substrate 1000, as shown in FIG. 2a. Then, the photoresist layer 1005 is removed. FIG. 2b shows a top view of the structure shown in FIG. 2a.

In the case of the present embodiment, one sidewall of the trench 1006 obtained by performing the wet etching is on the (111) plane of the silicon substrate 1000.

In the embodiment of the present invention, depositing the nitride layer 1004 on the oxide layer 1002 may be performed by, for example, thermal oxidation, Chemical Vapor Deposition (CVD), or other appropriate techniques; and depositing the nitride layer 1004 on the oxide layer 1002 may be performed by, for example, Chemical Vapor Deposition (CVD), Physical Vapor Deposition (PVD), Pulsed Laser Deposition (PLD), Atomic Layer Deposition (ALD), Plasma Enhanced Atomic Layer Deposition (PEALD), or other appropriate techniques. The oxide layer 1002 may be SiO₂ and the thickness thereof is about 20-40 nm. The nitride layer 1004 may be silicon nitride and the thickness thereof is about 30-150 nm.

In the embodiment of the present invention, in the above-mentioned wet etching operation, KOH, TMAH, or other chemical solution having high etching selectivity to the (111) plane of the silicon substrate is preferably used as the etchant.

Since the etchant, such as KOH or THAM, has high etching selectivity to the crystal plane of the silicon wafer, and the ratio between the etching rate at the (111) plane and the etching rate at other crystal planes is about 1:100, compared with forming the trenches 1006 by conventional dry etching, using the wet etching to form the trenches 1006 can, on the one hand, reduce damages caused to the sidewalls of the trenches during the manufacturing process, and, on the other hand, avoid the undercut caused under the sidewalls of the trenches to a great extent, thereby reducing the leakage current of the device and improving the performance, such as the breakdown characteristic, of the device.

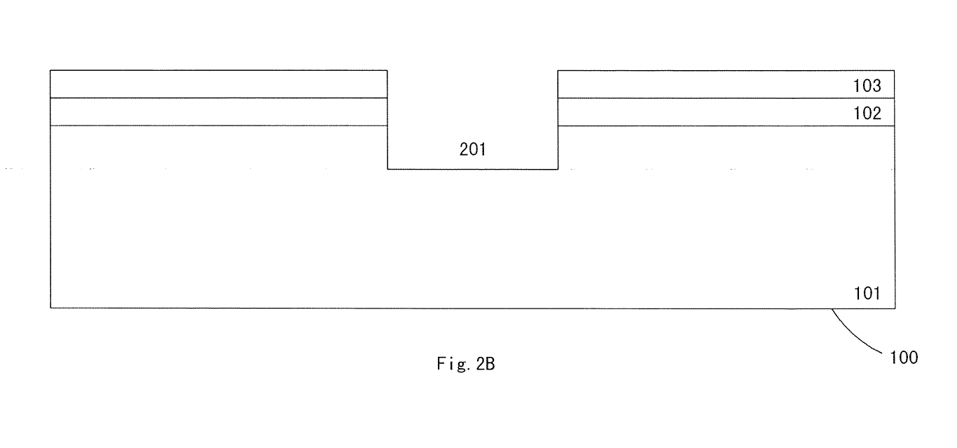

Next, the trenches 1006 are filled with an insulating material 1008. Then, a planarization operation is performed to remove the insulating material 1008 on the surface of the nitride layer 1004. So far, a first isolator that defines the width of the gate of the device is formed, as shown in FIG. 3.

In the embodiment of the present invention, filling the trenches 1006 with the insulating material 1008 can be performed by CVD, PVD, PLD, ALD, PEALD, or other appropriate techniques; removing the insulating material 1008 on the surface of the nitride layer 1004 can be performed by Chemical Mechanical Polishing (CMP) using the nitride layer 1004 as a stop layer; and the insulating material 1008 may be formed of one or more layers of oxide, nitride, or other appropriate materials.

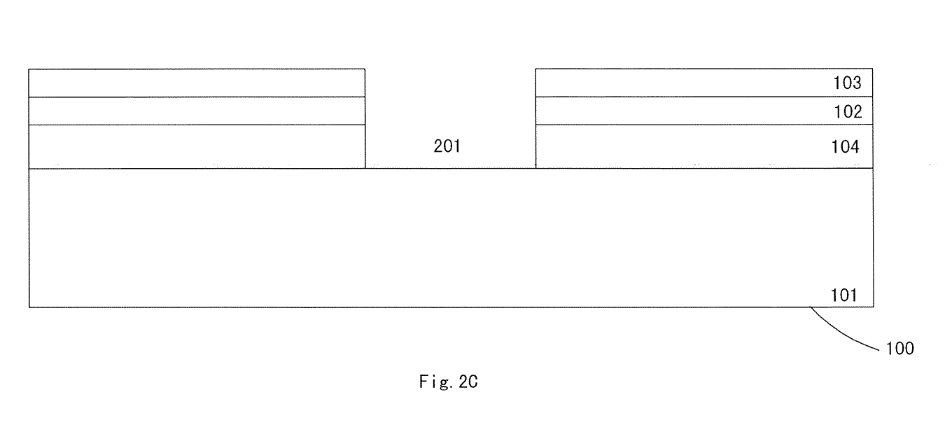

Then, a photoresist layer 1013 is coated on the surface of the structure shown in FIG. 3. The photoresist layer 1013 is patterned to form openings, the extension direction of which is perpendicular to the extension direction of the trenches 1006. That is, in the case of the present embodiment, the angle between the extension direction of the openings and the [111] direction is no more than 3°; preferably, the two directions are parallel to each other, as shown in FIG. 4a. The patterned photoresist layer 1013 is used as a mask to perform the dry etching operation so as to remove parts of the nitride layer 1004, the oxide layer 1002 and the silicon substrate 1000 under the openings, thereby forming trenches 1014 in the substrate 1000, as shown in FIG. 4a. Afterwards, the photoresist layer 1013 is removed. FIG. 4b shows a top view of the structure shown in FIG. 4a.

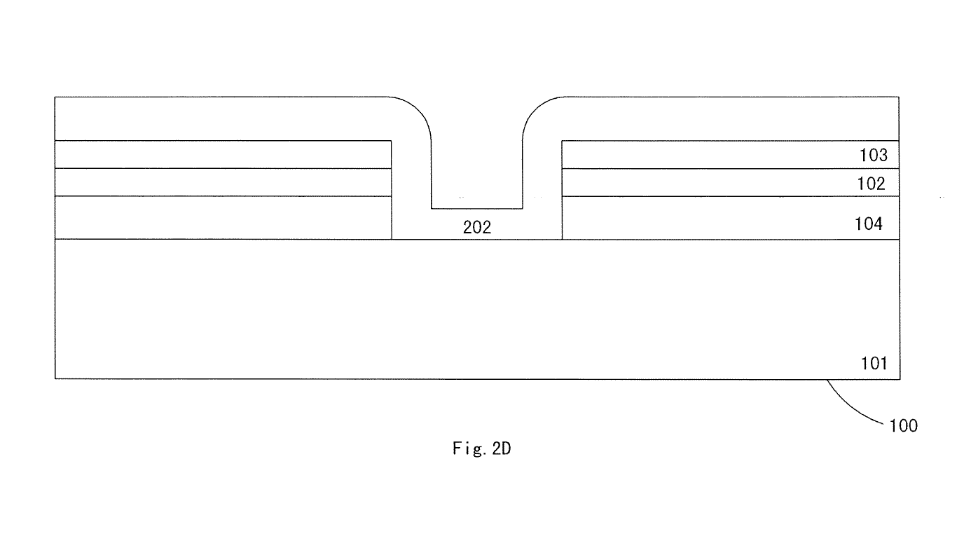

Next, the trenches 1014 are filled with an insulating material 1016. Then, a planarization operation is performed to remove the insulating material 1016 on the surface of the nitride layer 1004. So far, a second isolator that defines the length of the gate of the device is formed, as shown in FIG. 5a. FIG. 5b shows a top view of the structure shown in FIG. 5a. It can be seen from FIG. 5b that the first isolator is joined to the second isolator to define one or more isolation regions.

In the embodiment of the present invention, the dry etching operation can be performed by one of Reactive Ion Etching (RIE), Electron Cyclotron Resonance (ECR) etching, Inductively Coupled Plasma (ICP) etching, and the like; filling the trenches 1014 with the insulating material 1016 can be performed by CVD, PVD, PLD, ALD, PEALD, or other appropriate techniques; removing the insulating material 1016 on the surface of the nitride layer 1004 can be performed by CMP using the nitride layer 1004 as a stop layer; and the insulating material 1016 may be formed of oxide, nitride, or a combination thereof.

In the embodiment of the present invention, the first isolator and the second isolator each can be a Shallow Trench Isolation (STI) structure.

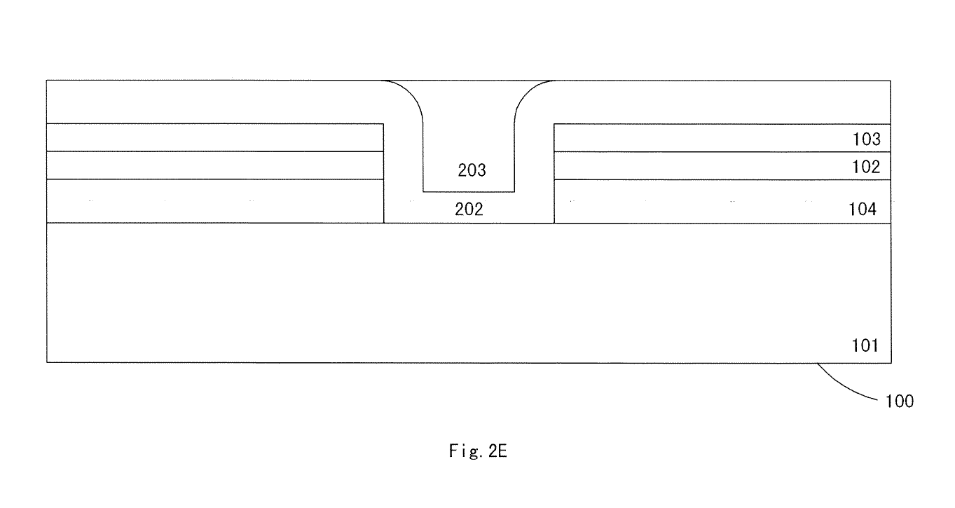

The method of forming the semiconductor structure having the gate according to an embodiment of the present invention will be described below with reference to FIG. 6.

Proceeding from FIG. 5a, a thin insulating layer is deposited on the structure shown in FIG. 5a. A gate dielectric layer is formed on the insulating layer. Then, a gate line is formed on the gate dielectric layer, which is between adjacent first isolators. The gate line is cut along a direction parallel to the second isolator so as to form one or more gates 1018 that are separated from each other. The two end portions of each of the one or more gates are located on the first isolator. Thus the semiconductor structure with the gates as shown in FIG. 6 is obtained.

After forming the gate structure, the source and drain regions on both sides of the gate may be formed by conventional techniques, thereby forming a transistor structure, and the details thereof will not be repeated here.

In the embodiment of the present invention, the insulating layer may be formed of an oxide; the gate dielectric layer may be either a conventional dielectric material or a high-k dielectric material; the process of forming the gate dielectric layer may comprise one of thermal oxidation, sputtering, and deposition, or other appropriate techniques. Cutting the gate line may be performed by conventional methods known to those skilled in the art, such as photolithography, masking followed by etching, for example, RIE or laser cutting etching, which will not be repeated here.

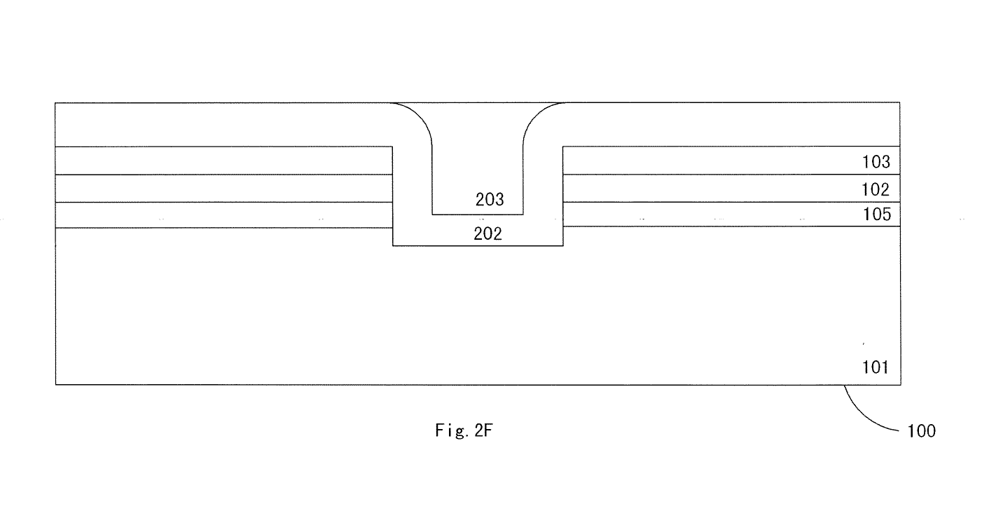

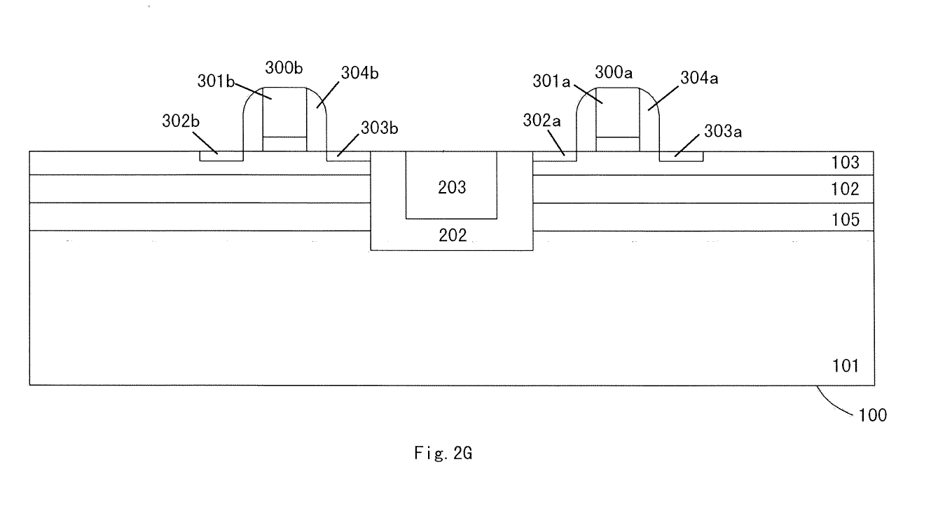

FIG. 7 shows a flow chart of the method of forming the isolation structure according to the embodiment of the present invention. In step S10, a silicon substrate having a (110) crystal plane or a (112) crystal plane is provided, and the [111] direction of the silicon substrate is determined In step S12, first trenches are formed in the silicon substrate by wet etching the silicon substrate, and the extension direction of the first trenches is substantially perpendicular to the [111] direction. In step S14, the first trenches are filled with a first insulating material to form a first isolator. In step S16, second trenches are formed in the silicon substrate by dry etching the silicon substrate, and the extension direction of the second trenches is perpendicular to the extension direction of the first trenches. In step S18, the second trenches are filled with a second insulating material to form a second isolator.

It can be seen from the above description that, in the present invention, the isolation structure between the devices is formed in two steps. In the first step, first trenches are formed in the silicon substrate first by wet etching so as to form a first isolator defining the width of the gate of the device. Since the present invention employs the silicon substrate of (110) crystal plane or (112) crystal plane, one sidewall of the formed first trench is on the (111) plane of the silicon substrate, and the wet etching uses an etchant such as KOH or TMAH that has high selectivity to the (111) plane of the silicon substrate, compared to the prior art, the present invention, on the one hand, reduces damages caused to the sidewalls of the trenches during the manufacturing process and reduces defects occurred in the sidewalls of the trenches so as to reduce the adverse effects on the gate of the device, and, on the other hand, minimizes the undercut caused under the sidewalls of the trenches, thereby reducing the leakage current of the device and improving the performance, such as the breakdown characteristic, of the device.

Then, in the second step, the second isolator perpendicular to the first isolator is formed by dry etching; the first isolator is joined to the second isolator to define one or more isolation regions.

While the present invention and advantages thereof have been described in details by way of the exemplary embodiments, those skilled in the art shall understand that many substitutions and variations may be made to the present invention without departing from the spirit and scope of the present invention defined by the appended claims.

What is claimed is:

1. A method of forming an isolation structure, comprising:
providing a silicon substrate having a (110) crystal plane or a (112) crystal plane;
forming one or more first trenches in a first direction of the silicon substrate by anisotropic wet etching;
filling the first trenches with a first insulating material to form one or more first isolators;
forming one or more second trenches in a second direction of the silicon substrate; and
filling the second trenches with a second insulating material to form one or more second isolators, the second isolators being joined to the first isolators to form the isolation structure; wherein the angle between the crystal orientation of one sidewall of the first trench and the [111] direction of the silicon substrate is no more than 3°.

2. The method according to claim 1, wherein the step of forming one or more first isolators by filling the first trenches with the first insulating material comprises:
filling the first trenches with the first insulating material; and
performing a planarization operation to remove the first insulating material on the plane where the surface of the silicon substrate is located.

3. The method according to claim 1, wherein the step of forming one or more second isolators by filling the second trenches with the second insulating material comprises:
filling the second trenches with the second insulating material; and
performing a planarization operation to remove the second insulating material on the plane where the surface of the silicon substrate is located.

4. The method according to claim 1, wherein the first direction is perpendicular to the second direction.

5. The method according to claim 1, wherein the first direction is parallel to the [111] direction of the silicon substrate.

6. The method according to claim 1, wherein the angle between the first direction and the [111] direction of the silicon substrate is no more than 3°.

7. The method according to claim 1, wherein one sidewall of the first trench is located on the (111) plane of the silicon substrate.

8. The method according to claim 1, wherein the first insulating material comprises one or more layers of oxide, nitride, or a combination thereof, and the second insulating material comprises one or more layers of oxide, SiN, or a combination thereof.

9. A method of forming a semiconductor structure, comprising: forming at least one isolation structure by a method comprising:
providing a silicon substrate having a (110) crystal plane or a (112) crystal plane;
forming one or more first trenches in a first direction of the silicon substrate by anisotropic wet etching;
filling the first trenches with a first insulating material to form one or more first isolators;
forming one or more second trenches in a second direction of the silicon substrate; and
filling the second trenches with a second insulating material to form one or more second isolators, the second isolators being joined to the first isolators to form the isolation structure;
wherein the angle between the crystal orientation of one sidewall of the first trench and the [111] direction of the silicon substrate is no more than 3°; and
forming one or more gates on regions isolated by the isolation structure, two end portions of each of the gates being located on corresponding one of the first isolators.

10. The method according to claim 9, wherein the step of forming one or more gates comprises:
forming gate lines parallel to the first direction;
cutting the gate lines parallel to the second direction on the first isolators to form one or more gates.

11. The method according to claim 9, wherein the step of forming one or more first isolators by filling the first trenches with the first insulating material comprises:
filling the first trenches with the first insulating material; and
performing a planarization operation to remove the first insulating material on the plane where the surface of the silicon substrate is located.

12. The method according to claim 9, wherein the step of forming one or more second isolators by filling the second trenches with the second insulating material comprises:
filling the second trenches with the second insulating material; and
performing a planarization operation to remove the second insulating material on the plane where the surface of the silicon substrate is located.

13. The method according to claim 9, wherein the first direction is perpendicular to the second direction.

14. The method according to claim 9, wherein the first direction is parallel to the [111] direction of the silicon substrate.

15. The method according to claim 9, wherein the angle between the first direction and the [111] direction of the silicon substrate is no more than 3°.

16. The method according to claim 9, wherein one sidewall of the first trench is located on the (111) plane of the silicon substrate.

17. The method according to claim 9, wherein the first insulating material comprises one or more layers of oxide, nitride, or a combination thereof, and the second insulating material comprises one or more layers of oxide, SiN, or a combination thereof.
